(19) United States
(12) Patent Application Publication
(10) Pub. No.: US 2026/0113963 A1
(43) Pub. Date: Apr. 23, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Kohei SAKO, Tokyo (JP); Hiroshi UMEDA, Tokyo (JP); Kazuya KONISHI, Tokyo (JP)

(73) Assignee: Mitsubishi Electric Corporation, Tokyo (JP)

(21) Appl. No.: 19/348,488

(22) Filed: Oct. 2, 2025

(30) Foreign Application Priority Data
Oct. 23, 2024 (JP) 2024-186633

(51) Int. Cl. H10D 12/00; H10D 12/01; H10D 64/00

(52) U.S. Cl. CPC H10D 12/481; H10D 12/038; H10D 64/117

(57) ABSTRACT

A semiconductor device includes a semiconductor substrate and a first trench structure. The first trench structure includes: a lower electrode that is provided on a lower portion of a trench that is provided on a first main surface of the semiconductor substrate, with a first insulating film interposed therebetween; and an upper electrode that is insulated from the lower electrode by a second insulating film, and is provided on an upper portion of the trench with a third insulating film interposed therebetween. A ratio of crystal orientation being the orientation of a (111) plane orientation is higher in the lower electrode than in the upper electrode.

### BACKGROUND

### Technical Field

The present disclosure relates to a semiconductor device and a method of manufacturing the semiconductor device.

### Description of the Background Art

In recent years, in order to reduce a switching loss, a semiconductor device including an upper electrode and a lower electrode that are insulated from each other in a trench has been proposed (for example, Japanese Patent Application Laid-Open No. 2006-324570).

In the semiconductor device, as described above, a small protrusion is generated on an upper surface of the lower electrode in some cases. In such cases, a portion that is in contact with the protrusion is thin in an insulating film between the upper electrode and the lower electrode, and therefore there has been a possibility that insulation between the upper electrode and the lower electrode deteriorates.

### SUMMARY

The present disclosure has been made in view of the problems described above, and an object of the present disclosure is to provide a technique that is capable of enhancing insulation between an upper electrode and a lower electrode.

A semiconductor device according to the present disclosure includes: a semiconductor substrate that includes a first main surface; and a first trench structure that is provided on a side of the first main surface of the semiconductor substrate, wherein the first trench structure includes: a lower electrode that is provided on a lower portion of a trench that is provided on the first main surface of the semiconductor substrate, with a first insulating film interposed between the trench and the lower electrode; and an upper electrode that is insulated from the lower electrode by a second insulating film, and is provided on an upper portion of the trench with a third insulating film interposed between the trench and the upper electrode, the upper electrode is electrically connected to a first gate electrode, and a ratio of crystal orientation being orientation of a (111) plane orientation is higher in the lower electrode than in the upper electrode.

Insulation between the upper electrode and the lower electrode can be enhanced.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIGS. 1 and 2 are cross-sectional views each illustrating a configuration of a semiconductor device according to a first preferred embodiment;

FIGS. 3A to 3C are cross-sectional views illustrating a method of manufacturing the semiconductor device according to the present first preferred embodiment;

FIGS. 4 and 5 are cross-sectional views each illustrating a configuration of a semiconductor device according to a third variation;

FIG. 6 is a cross-sectional view illustrating a configuration of a semiconductor device according to a fourth variation;

FIG. 7 is a cross-sectional view illustrating a configuration of a semiconductor device according to a second preferred embodiment; and

FIG. 8 is a cross-sectional view illustrating a configuration of a semiconductor device according to a third preferred embodiment.

### DESCRIPTION OF THE PREFERRED EMBODIMENTS

Hereinafter, preferred embodiments will be described with reference to the accompanying drawings. Features described in each of the preferred embodiments described below are examples, and all of the features are not necessarily essential. In the description below, components that are similar in a plurality of preferred embodiments are denoted by the same or similar reference sign, and different components will be mainly described. Furthermore, in the description below, specified positions and directions, such as “upper”, “lower”, “left-hand”, “right-hand”, “front”, or “back”, may not necessarily match positions and directions in actual implementation. In addition, a fact that the concentration of a certain portion is higher than that of another portion may mean, for example, that the average of the concentration of the certain portion is higher than the average of the concentration of the other portion. In contrast, a fact that the concentration of a certain portion is lower than that of another portion may mean, for example, that the average of the concentration of the certain portion is lower than the average of the concentration of the other portion. Furthermore, the description below will be provided under the assumption that a first conductivity type is an n-type, and a second conductivity type is a p-type, but the first conductivity type may be the p-type, and the second conductivity type may be the n-type.

### First Preferred Embodiment

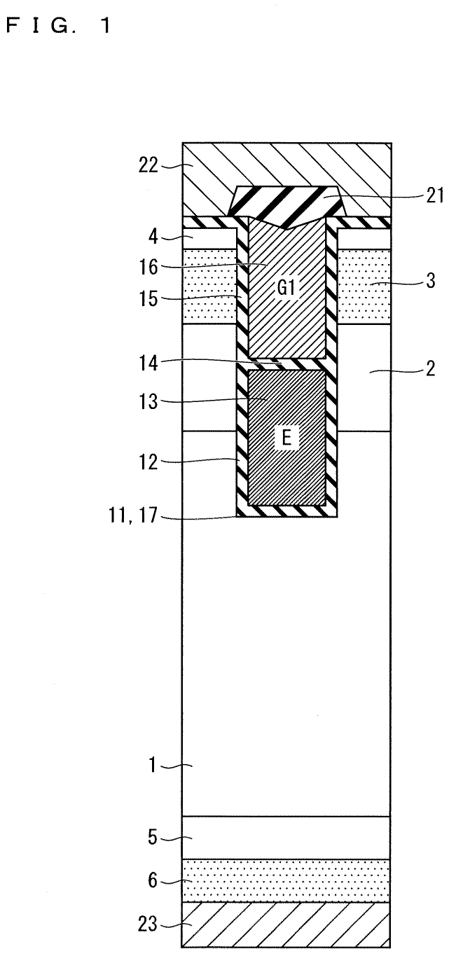

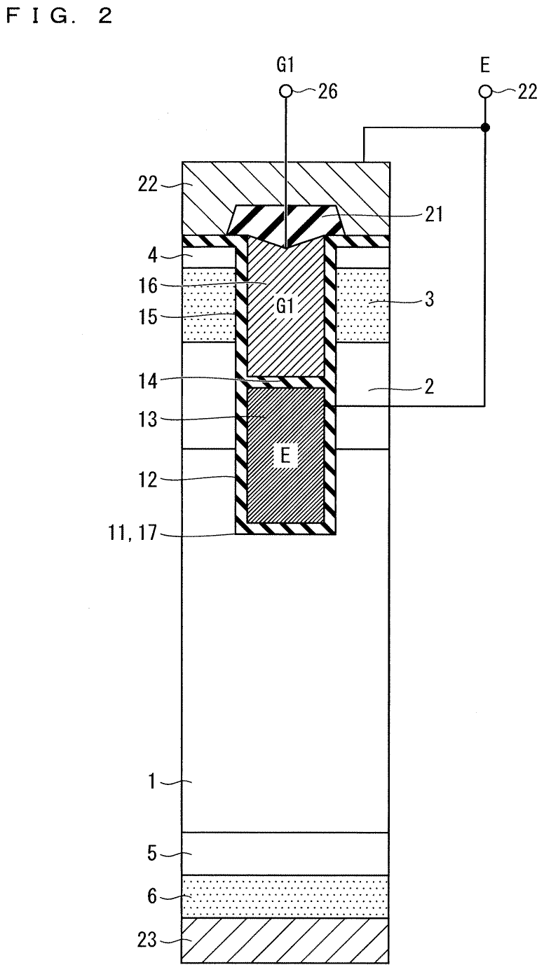

FIGS. 1 and 2 are cross-sectional views each illustrating a configuration of a semiconductor device according to the present first preferred embodiment. Hereinafter, description will be provided by using, as an example, a configuration in which the semiconductor device is an insulated gate bipolar transistor (IGBT), but this is not restrictive. The semiconductor device may be, for example, a metal oxide semiconductor field effect transistor (MOSFET), or may be a reverse conducting-IGBT (RC-IGBT) that includes an IGBT region provided with an IGBT, and a diode region provided with a Schottky barrier diode (SBD), a PN junction diode (PND), and the like.

The semiconductor device of FIG. 1 includes a semiconductor substrate, a first trench structure 11, an interlayer insulating film 21, an emitter electrode 22, and a collector electrode 23.

The semiconductor substrate includes an n⁻-type drift layer 1, an n-type carrier accumulation layer 2, a p-type base layer 3, an n⁺-type source layer 4, an n-type buffer layer 5, and a p-type collector layer 6. The semiconductor substrate includes a first main surface that corresponds to an upper end of the source layer 4, and a second main surface that corresponds to a lower end of the collector layer 6.

Note that the semiconductor substrate may be constituted by a normal semiconductor wafer, or may be constituted by an epitaxial growth layer. Furthermore, the semiconductor substrate may be constituted by normal silicon (Si), or may be constituted by a wide band gap semiconductor such as silicon carbide (SiC), gallium nitride (GaN), gallium oxide (Ga₂O₃), or diamond. In a case where the semiconductor substrate is constituted by the wide band gap semiconductor, the semiconductor device can stably operate at a high temperature and at a high voltage, and the switching speed of the semiconductor device can be increased.

Next, each layer of the semiconductor substrate will be described. On a first main surface side of the drift layer 1, the carrier accumulation layer 2 having an n-type impurity concentration that is higher than that of the drift layer 1 is provided. On the first main surface side of the carrier accumulation layer 2, the base layer 3 is provided. On the first main surface side of the base layer 3, the source layer 4 having an n-type impurity concentration that is higher than that of the carrier accumulation layer 2 is provided.

As described above, in the semiconductor substrate according to the present first preferred embodiment, the drift layer 1, the carrier accumulation layer 2, the base layer 3, and the source layer 4 are provided in this order toward the first main surface. On the other hand, in the semiconductor substrate, the drift layer 1, the buffer layer 5, and the collector layer 6 are provided in this order toward the second main surface. The respective layers of the semiconductor substrate are selectively formed by performing, for example, mask formation and ion implantation.

The first trench structure 11 includes a lower insulating film 12 serving as a first insulating film, a lower electrode 13, a boundary insulating film 14 serving as a second insulating film, an upper insulating film 15 serving as a third insulating film, and an upper electrode 16, and is provided on the first main surface side of the semiconductor substrate.

The lower insulating film 12 is provided in a lower portion of a trench 17 that penetrates the source layer 4, the base layer 3, and the carrier accumulation layer 2 from the first main surface of the semiconductor substrate and reaches the drift layer 1. The lower insulating film 12 is formed by performing, for example, thermal oxidation and chemical vapor deposition (CVD).

The lower electrode 13 is provided on the lower portion of the trench 17 with the lower insulating film 12 interposed therebetween. The lower electrode 13 is made of, for example, polycrystalline silicon obtained by crystallizing amorphous silicon containing impurities. As illustrated in FIG. 2, the lower electrode 13 is electrically connected to the emitter electrode 22.

The boundary insulating film 14 of FIG. 1 is provided on an upper portion of the lower electrode 13. The boundary insulating film 14 includes an oxide film obtained by thermally oxidizing the upper portion of the lower electrode 13. The boundary insulating film 14 may have a two-layer structure that includes the oxide film, and a CVD film provided thereon, or may have a three-layer structure that includes the two-layer structure, and an oxide film provided thereon. In FIG. 1, the boundary insulating film 14 is a flat film, but may be a film having a protrusion in which a central portion protrudes toward the upper electrode 16, as described later.

The upper insulating film 15 is provided in an upper portion of the trench 17. The upper insulating film 15 is formed by performing, for example, thermal oxidation and CVD. The upper electrode 16 is insulated from the lower electrode 13 by the boundary insulating film 14 in the trench 17, and is provided on the upper portion of the trench 17 with the upper insulating film 15 interposed therebetween. A position of a lower end of the upper electrode 16 is located below a position of a lower end of the base layer 3. The upper electrode 16 is made of, for example, doped polysilicon containing impurities. As illustrated in FIG. 2, the upper electrode 16 is electrically connected to a first gate electrode 26. The first gate electrode 26 is provided on the semiconductor substrate similarly to the emitter electrode 22, and corresponds to a first gate pad to which a first gate potential is applied from the outside, but this is not illustrated.

In the present first preferred embodiment, a ratio of crystal orientation being the orientation of the (111) plane orientation is higher in the lower electrode 13 than in the upper electrode 16, and the average grain size of crystals is larger in the lower electrode 13 than in the upper electrode 16. However, it is not essential that the average grain size of crystals is larger in the lower electrode 13 than in the upper electrode 16.

The interlayer insulating film 21 of FIG. 1 is provided on the upper electrode 16. The emitter electrode 22 is provided to cover the source layer 4 and the interlayer insulating film 21, is electrically connected to the source layer 4 in, for example, a cross section other than the cross section of FIG. 1, and is insulated from the upper electrode 16 by the interlayer insulating film 21. The collector electrode 23 is provided to cover the collector layer 6, and is electrically connected to the collector layer 6.

### Manufacturing Method

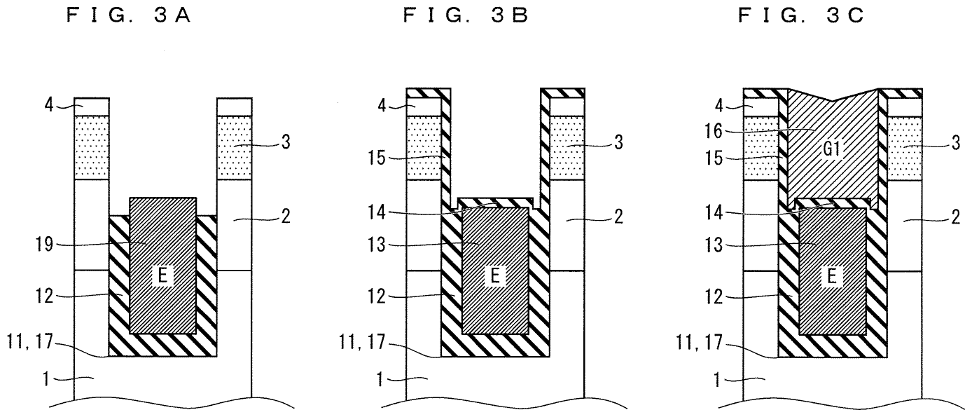

FIGS. 3A, 3B, and 3C are cross-sectional views illustrating a method of manufacturing the semiconductor device according to the present first preferred embodiment. Here, a manufacturing method relating to the first trench structure 11 will be mainly described.

First, a semiconductor substrate in which respective layers, such as the drift layer 1 or the carrier accumulation layer 2, and the trench 17 have been provided is prepared. Such a semiconductor substrate is formed by performing, for example, mask formation and ion implantation for selectively forming the respective layers, and etching for forming the trench 17.

As illustrated in FIG. 3A, the lower insulating film 12 is formed in the lower portion of the trench 17 by performing, for example, thermal oxidation and CVD, and then a conductive member 19 is formed on the lower portion of the trench 17 with the lower insulating film 12 interposed therebetween by performing, for example, CVD. The conductive member 19 is made of, for example, amorphous silicon containing impurities.

Next, as illustrated in FIG. 3B, an upper portion of the conductive member 19 is thermally oxidized to form the boundary insulating film 14 from the upper portion of the conductive member 19, and the lower electrode 13 is formed from a remaining portion of the conductive member 19 by using the temperature of thermal oxidation. In the example of FIG. 3B, the boundary insulating film 14 formed by thermally oxidizing the upper portion of the conductive member 19 includes a protrusion in which a central portion protrudes upward, but this is not essential.

Furthermore, in the example of FIG. 3B, when the boundary insulating film 14 is formed by performing thermal oxidation, the upper insulating film 15 is formed by thermally oxidizing the upper portion of the trench 17. However, this is not restrictive, and after the boundary insulating film 14 has been formed by performing thermal oxidation, the upper insulating film 15 may be formed by thermally oxidizing the upper portion of the trench 17, or performing CVD on the upper portion of the trench 17.

Then, as illustrated in FIG. 3C, the upper electrode 16 that is insulated from the lower electrode 13 by the boundary insulating film 14 is formed on the upper portion of the trench 17 with the upper insulating film 15 interposed therebetween by performing, for example, CVD. The upper electrode 16 is made of, for example, doped polysilicon containing impurities. Thereafter, the interlayer insulating film 21 or the like is formed, and the semiconductor device according to the present first preferred embodiment is completed.

### Conclusion of First Preferred Embodiment

Normally, the speed of formation of an oxide film in a case where the crystal orientation of silicon is the orientation of the (111) plane orientation is higher than the speed of formation of an oxide film in a case where the crystal orientation of silicon is the orientation of the (100) plane orientation.

Here, in the present first preferred embodiment, a ratio of crystal orientation being the orientation of the (111) plane orientation is higher in the lower electrode 13 than in the upper electrode 16. By employing such a configuration, the speed of formation of the boundary insulating film 14 can be increased in comparison with a configuration in which the ratio described above of the lower electrode 13 is lower than or equal to the ratio described above of the upper electrode 16, and this can thicken the boundary insulating film 14. As a result, insulation between the upper electrode 16 and the lower electrode 13 can be enhanced, and this can increase a gate breakdown voltage. Furthermore, an increase in the speed of formation of the boundary insulating film 14 can reduce the time of formation of the boundary insulating film 14.

In general, it is preferable that the film thickness of the upper insulating film 15 that affects a threshold voltage of a channel be small, but it is preferable that the film thickness of the boundary insulating film 14 that affects insulation between the upper electrode 16 and the lower electrode 13 be great. On the other hand, when thermal oxidation is performed to form the boundary insulating film 14, if the upper portion of the trench 17 is thermally oxidized to form the upper insulating film 15, that is, if the boundary insulating film 14 and the upper insulating film 15 are formed in parallel, a manufacturing process can be simplified.

However, in a conventional manufacturing method, it is difficult to reduce a film thickness of the upper insulating film 15 and increase a film thickness of the boundary insulating film 14. In contrast, in a case where the boundary insulating film 14 and the upper insulating film 15 are formed in parallel, if the configuration described above according to the present first preferred embodiment is applied, it is possible to form a configuration in which the film thickness of the upper insulating film 15 is reduced and the film thickness of the boundary insulating film 14 is increased, while simplifying the manufacturing process.

Furthermore, in general, in a case where an electrode having a small average grain size of crystals has been oxidized, some of the crystals move such that the compressive stress of polycrystalline silicon in the electrode does not increase, and therefore a protrusion that is smaller than the protrusion of FIG. 3B is generated on a surface of the electrode in some cases. In contrast, in the present first preferred embodiment, the average grain size of crystals is larger in the lower electrode 13 than in the upper electrode 16. By employing such a configuration, the average grain size of crystals of the lower electrode 13 can be relatively increased, and therefore a protrusion that partially makes the boundary insulating film 14 thin can be prevented from being generated on the upper surface of the lower electrode 13. As a result, insulation between the upper electrode 16 and the lower electrode 13 can be enhanced.

### First Variation

In the first preferred embodiment, the average grain size of the lower electrode 13 is preferably 0.5 μm or more and 4.0 μm or less, and more preferably, 0.8 μm or more and 4.0 μm or less. Alternatively, the average grain size of the lower electrode 13 is preferably 1.1 times or more the average grain size of the upper electrode 16, and 4.0 μm or less. By employing such a configuration, the average grain size of crystals of the lower electrode 13 can be relatively increased, and therefore a protrusion that partially makes the boundary insulating film 14 thin can be prevented from being generated on the upper portion of the lower electrode 13. As a result, insulation between the upper electrode 16 and the lower electrode 13 can be enhanced.

### Second Variation

In the first preferred embodiment, the concentration of impurities may be higher in the lower electrode 13 than in the upper electrode 16. The impurities described here are impurities such as phosphorus, but this is not restrictive. By employing such a configuration, the speed of oxidation of the lower electrode 13, that is, the speed of formation of the boundary insulating film 14 can be increased, and this can thicken the boundary insulating film 14. As a result, insulation between the upper electrode 16 and the lower electrode 13 can be enhanced.

Furthermore, in the first preferred embodiment, the concentration of impurities may be lower in the lower electrode 13 than in the upper electrode 16. The impurities described here are impurities such as phosphorus similarly to the above, but this is not restrictive. By employing such a configuration, in a case where a voltage has been applied to the upper electrode 16, an amount of electrons captured by the boundary insulating film 14 from the upper electrode 16 can be reduced, and this can reduce hysteresis in gate leak characteristics.

### Third Variation

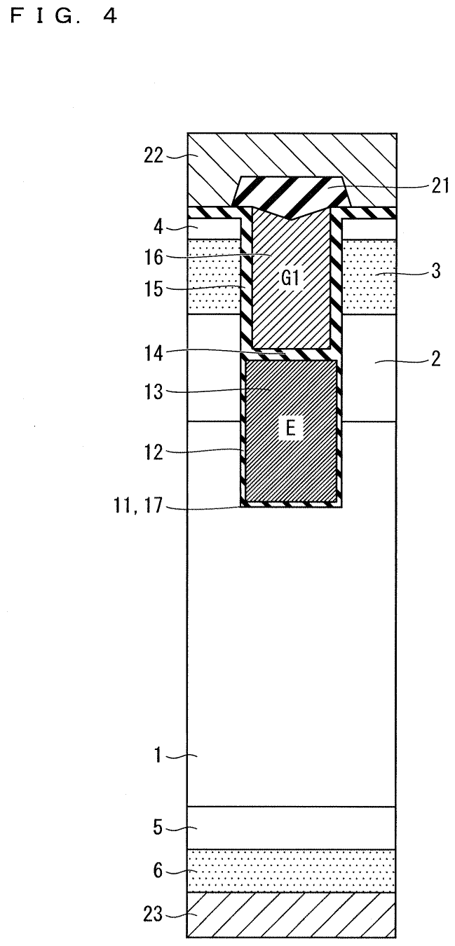

In the first preferred embodiment, as illustrated in FIG. 4, the thickness of the lower insulating film 12 that is in contact with a side of the lower electrode 13 may be smaller than the thickness of the upper insulating film 15 that is in contact with a side of the upper electrode 16. By employing such a configuration, the area of the lower electrode 13 that faces the upper electrode 16 can be reduced, and this can increase the gate breakdown voltage. Furthermore, the volume of the lower electrode 13 may be larger than the volume of the upper electrode 16. By employing such a configuration, a path of a gate current can be reduced, and this can increase the gate breakdown voltage.

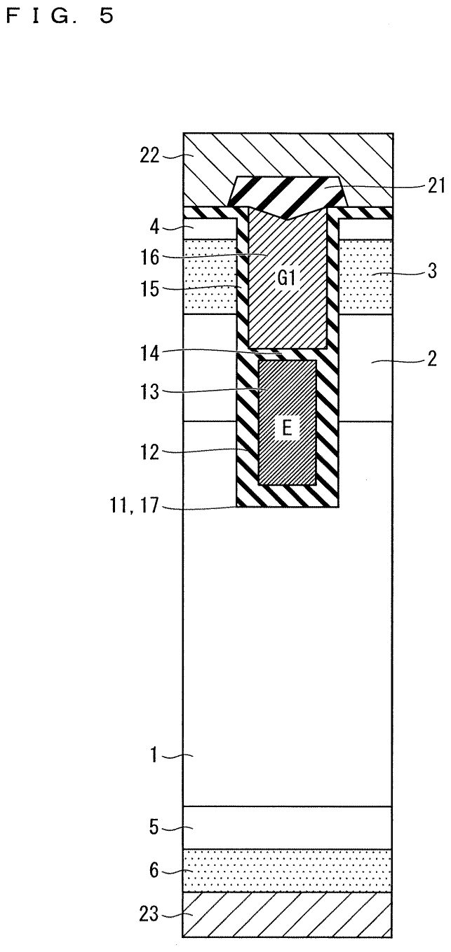

Furthermore, in the first preferred embodiment, as illustrated in FIG. 5, the thickness of the lower insulating film 12 that is in contact with the side of the lower electrode 13 may be greater than the thickness of the upper insulating film 15 that is in contact with the side of the upper electrode 16. By employing such a configuration, the area of the lower electrode 13 that faces the upper electrode 16 can be reduced, and this can increase the gate breakdown voltage. Furthermore, the volume of the lower electrode 13 may be smaller than the volume of the upper electrode 16. By employing such a configuration, a path of a gate current can be reduced, and this can increase the gate breakdown voltage.

### Fourth Variation

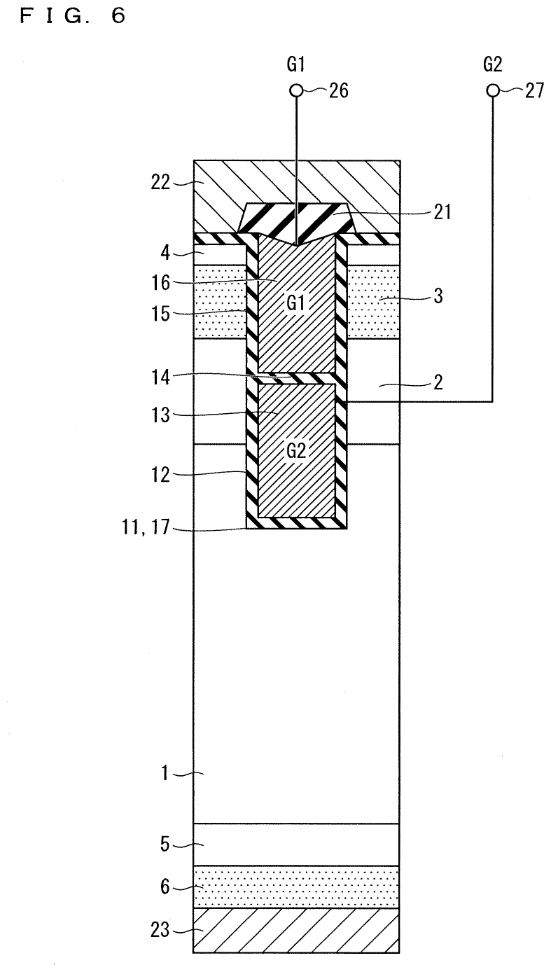

In the first preferred embodiment, as illustrated in FIG. 2, the upper electrode 16 is electrically connected to the first gate electrode 26, and the lower electrode 13 is electrically connected to the emitter electrode 22, but this is not restrictive. As illustrated in FIG. 6, a configuration in which the upper electrode 16 is electrically connected to the first gate electrode 26, and the lower electrode 13 is electrically connected to a second gate electrode 27 that is different in voltage control from the first gate electrode 26, may be employed.

For example, voltage control may be performed on the first gate electrode 26 and the second gate electrode 27 in such a way that a signal of the second gate electrode 27 rises at a timing earlier than a timing of a signal of the first gate electrode 26, and falls at a timing later than a timing of the signal of the first gate electrode 26. The second gate electrode 27 is provided on the semiconductor substrate similarly to the emitter electrode 22, and corresponds to a second gate pad to which a second gate potential is applied from the outside, but this is not illustrated. The second gate electrode 27 and the second gate pad are referred to as a control gate electrode and a control gate pad, respectively, in some cases.

By employing such a configuration, the area where a gate potential and an emitter potential are adjacent to each other can be reduced in comparison with a configuration in which one of the upper electrode 16 and the lower electrode 13 is electrically connected to the first gate electrode 26, and another is electrically connected to the emitter electrode 22. Therefore, the gate breakdown voltage of the semiconductor device can be improved.

### Second Preferred Embodiment

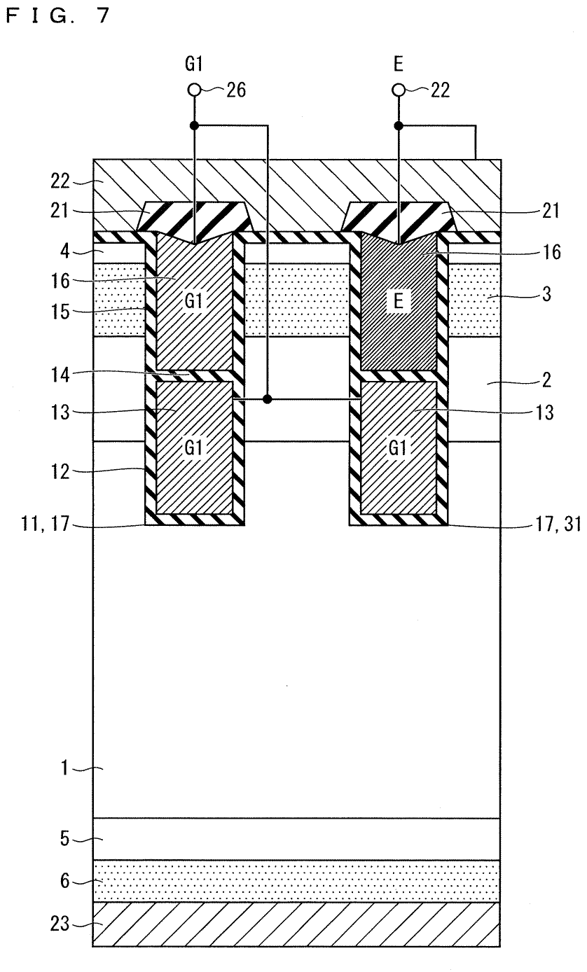

FIG. 7 is a cross-sectional view illustrating a configuration of a semiconductor device according to the present second preferred embodiment. As illustrated in FIG. 7, in the present second preferred embodiment, the upper electrode 16 and the lower electrode 13 are electrically connected to the first gate electrode 26. By employing such a configuration, the area where a gate potential and an emitter potential are adjacent to each other can be reduced in comparison with a configuration in which one of the upper electrode 16 and the lower electrode 13 is electrically connected to the first gate electrode 26, and another is electrically connected to the emitter electrode 22. Therefore, the breakdown voltage of the semiconductor device can be improved.

Furthermore, in the present second preferred embodiment, on the first main surface side of the semiconductor substrate, not only the first trench structure 11 but also a second trench structure 31 is provided. The second trench structure 31 is a structure that corresponds to the first trench structure 11, that is, a structure that is similar to the first trench structure 11. However, in the second trench structure 31, the upper electrode 16 is electrically connected to the emitter electrode 22, and the lower electrode 13 is electrically connected to the first gate electrode 26.

By employing such a configuration, the lower electrode 13 of the second trench structure 31 is electrically connected to the first gate electrode 26, and therefore a capacity between the lower electrode 13 of the second trench structure 31 and the collector layer 6 can be changed. Such a change in capacity can improve the switching loss.

### Third Preferred Embodiment

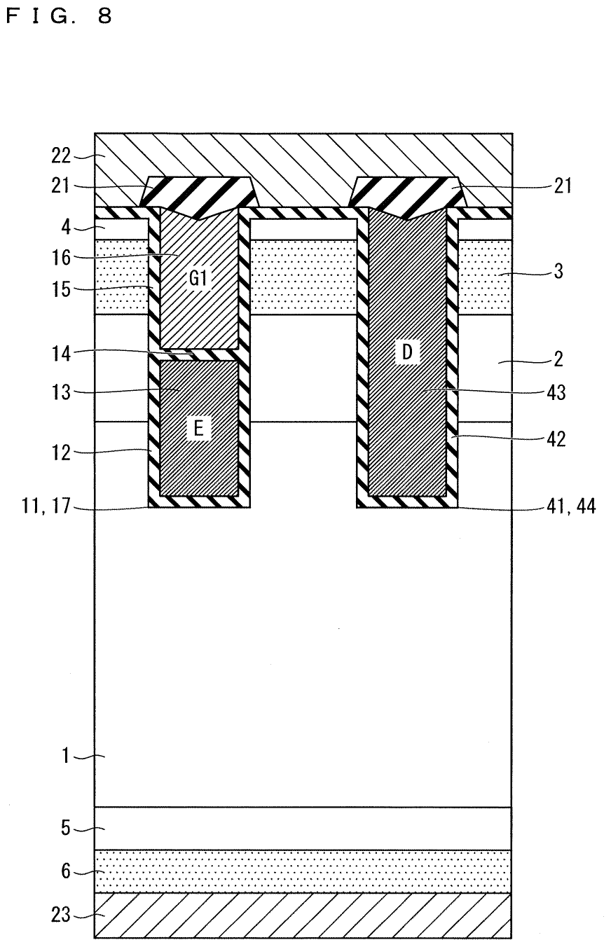

FIG. 8 is a cross-sectional view illustrating a configuration of a semiconductor device according to the present third preferred embodiment. As illustrated in FIG. 8, in the present third preferred embodiment, on the first main surface side of the semiconductor substrate, not only the first trench structure 11 but also a dummy trench structure 41 is provided.

The dummy trench structure 41 includes an insulating film 42 and a dummy electrode 43. A trench 44 that penetrates the source layer 4, the base layer 3, and the carrier accumulation layer 2 from the first main surface of the semiconductor substrate and reaches the drift layer 1 is provided on the first main surface side of the semiconductor substrate. The dummy electrode 43 is provided on the trench 44 with the insulating film 42 interposed therebetween. The dummy electrode 43 is electrically connected to an electrode other than a gate electrode such as the first gate electrode 26 or the second gate electrode 27, for example, the emitter electrode 22, or is electrically connected to a floating electrode.

By employing such a configuration, an electric field that is applied to the first trench structure 11 can be shared by the dummy trench structure 41, and therefore the gate breakdown voltage of the semiconductor device can be improved. Note that the dummy trench structure 41 described above includes the one-stage dummy electrode 43, but this is not restrictive. For example, the dummy trench structure 41 may include two-stage dummy electrodes similarly to the upper electrode 16 and the lower electrode 13 of the first trench structure 11.

In the present disclosure in English, ‘a’ and ‘an’ mean one or more. Thus, ‘a’, ‘an’, ‘one or more’, and ‘at least one’can be equivalently used.

Note that respective preferred embodiments and respective variations can be freely combined, or variations or omissions can be appropriately made to the respective preferred embodiments and the respective variations.

Hereinafter, various aspects of the present disclosure will be collectively described as appendices.

### Appendix 1

A semiconductor device comprising:
a semiconductor substrate that includes a first main surface; and
a first trench structure that is provided on a side of the first main surface of the semiconductor substrate, wherein
the first trench structure includes:
a lower electrode that is provided on a lower portion of a trench that is provided on the first main surface of the semiconductor substrate, with a first insulating film interposed between the trench and the lower electrode; and
an upper electrode that is insulated from the lower electrode by a second insulating film, and is provided on an upper portion of the trench with a third insulating film interposed between the trench and the upper electrode,
the upper electrode is electrically connected to a first gate electrode, and
a ratio of crystal orientation being orientation of a (111) plane orientation is higher in the lower electrode than in the upper electrode.

### Appendix 2

The semiconductor device according to appendix 1, wherein
an average grain size of crystals is larger in the lower electrode than in the upper electrode.

### Appendix 3

The semiconductor device according to appendix 1, wherein
an average grain size of the lower electrode is 0.5 μm or more and 4.0 μm or less.

### Appendix 4

The semiconductor device according to appendix 1, wherein
an average grain size of the lower electrode is 0.8 μm or more and 4.0 μm or less.

### Appendix 5

The semiconductor device according to appendix 1, wherein
an average grain size of the lower electrode is 1.1 times or more the average grain size of the upper electrode, and 4.0 μm or less.

### Appendix 6

The semiconductor device according to any one of appendices 1 to 5, wherein
concentration of impurities is higher in the lower electrode than in the upper electrode.

### Appendix 7

The semiconductor device according to any one of appendices 1 to 5, wherein
concentration of impurities is lower in the lower electrode than in the upper electrode.

### Appendix 8

The semiconductor device according to any one of appendices 1 to 7, wherein
a thickness of the first insulating film that is in contact with a side of the lower electrode is smaller than a thickness of the third insulating film that is in contact with a side of the upper electrode.

### Appendix 9

The semiconductor device according to any one of appendices 1 to 7, wherein
a thickness of the first insulating film that is in contact with a side of the lower electrode is greater than a thickness of the third insulating film that is in contact with a side of the upper electrode.

### Appendix 10

The semiconductor device according to any one of appendices 1 to 9, wherein
a volume of the lower electrode is smaller than a volume of the upper electrode.

### Appendix 11

The semiconductor device according to any one of appendices 1 to 9, wherein
a volume of the lower electrode is larger than the volume of a upper electrode.

### Appendix 12

The semiconductor device according to any one of appendices 1 to 11, wherein
the lower electrode is electrically connected to the first gate electrode.

### Appendix 13

The semiconductor device according to any one of appendices 1 to 11, wherein
the lower electrode is electrically connected to a second gate electrode that is different in voltage control from the first gate electrode.

### Appendix 14

The semiconductor device according to any one of appendices 1 to 13, further comprising
a second trench structure that is a structure that corresponds to the first trench structure, and in which the upper electrode is electrically connected to an emitter electrode, and the lower electrode is electrically connected to the first gate electrode.

### Appendix 15

The semiconductor device according to any one of appendices 1 to 14, further comprising
a dummy trench structure that is provided on the side of the first main surface of the semiconductor substrate.

### Appendix 16

A method of manufacturing a semiconductor device, the method comprising:
a process of preparing a semiconductor substrate that includes a first main surface that is provided with a trench;
a process of forming a conductive member on a lower portion of the trench with a first insulating film interposed between the trench and the conductive member;
a process of thermally oxidizing an upper portion of the conductive member to form a second insulating film from the upper portion of the conductive member, and form a lower electrode from a remaining portion of the conductive member; and
a process of forming an upper electrode on an upper portion of the trench with a third insulating film interposed between the trench and the upper electrode, the upper electrode being insulated from the lower electrode by the second insulating film, wherein
the upper electrode is connected to a first gate electrode, and
a ratio of crystal orientation being orientation of a (111) plane orientation is higher in the lower electrode than in the upper electrode.

### Appendix 17

The method of manufacturing the semiconductor device according to appendix 16, wherein
when thermal oxidation is performed to form the second insulating film, the upper portion of the trench is thermally oxidized to form the third insulating film.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate that includes a first main surface; and
a first trench structure that is provided on a side of the first main surface of the semiconductor substrate, wherein the first trench structure includes:
a lower electrode that is provided on a lower portion of a trench that is provided on the first main surface of the semiconductor substrate, with a first insulating film interposed between the trench and the lower electrode; and
an upper electrode that is insulated from the lower electrode by a second insulating film, and is provided on an upper portion of the trench with a third insulating film interposed between the trench and the upper electrode,
the upper electrode is electrically connected to a first gate electrode, and
a ratio of crystal orientation being orientation of a (111) plane orientation is higher in the lower electrode than in the upper electrode.

2. The semiconductor device according to claim 1, wherein
an average grain size of crystals is larger in the lower electrode than in the upper electrode.

3. The semiconductor device according to claim 1, wherein an average grain size of the lower electrode is 0.5 μm or more and 4.0 μm or less.

4. The semiconductor device according to claim 1, wherein an average grain size of the lower electrode is 0.8 μm or more and 4.0 μm or less.

5. The semiconductor device according to claim 1, wherein
an average grain size of the lower electrode is 1.1 times or more the average grain size of the upper electrode, and 4.0 μm or less.

6. The semiconductor device according to claim 1, wherein
concentration of impurities is higher in the lower electrode than in the upper electrode.

7. The semiconductor device according to claim 1, wherein
concentration of impurities is lower in the lower electrode than in the upper electrode.

8. The semiconductor device according to claim 1, wherein
a thickness of the first insulating film that is in contact with a side of the lower electrode is smaller than a thickness of the third insulating film that is in contact with a side of the upper electrode.

9. The semiconductor device according to claim 1, wherein
a thickness of the first insulating film that is in contact with a side of the lower electrode is greater than a thickness of the third insulating film that is in contact with a side of the upper electrode.

10. The semiconductor device according to claim 1, wherein a volume of the lower electrode is smaller than a volume of the upper electrode.

11. The semiconductor device according to claim 1, wherein a volume of the lower electrode is larger than a volume of the upper electrode.

12. The semiconductor device according to claim 1, wherein the lower electrode is electrically connected to the first gate electrode.

13. The semiconductor device according to claim 1, wherein
the lower electrode is electrically connected to a second gate electrode that is different in voltage control from the first gate electrode.

14. The semiconductor device according to claim 1, further comprising
a second trench structure that is a structure that corresponds to the first trench structure, and in which the upper electrode is electrically connected to an emitter electrode, and the lower electrode is electrically connected to the first gate electrode.

15. The semiconductor device according to claim 1, further comprising
a dummy trench structure that is provided on the side of the first main surface of the semiconductor substrate.

16. A method of manufacturing a semiconductor device, the method comprising:
a process of preparing a semiconductor substrate that includes a first main surface that is provided with a trench;
a process of forming a conductive member on a lower portion of the trench with a first insulating film interposed between the trench and the conductive member;
a process of thermally oxidizing an upper portion of the conductive member to form a second insulating film from the upper portion of the conductive member, and form a lower electrode from a remaining portion of the conductive member; and
a process of forming an upper electrode on an upper portion of the trench with a third insulating film interposed between the trench and the upper electrode, the upper electrode being insulated from the lower electrode by the second insulating film, wherein the upper electrode is connected to a first gate electrode, and
a ratio of crystal orientation being orientation of a (111) plane orientation is higher in the lower electrode than in the upper electrode.

17. The method of manufacturing the semiconductor device according to claim 16, wherein
when thermal oxidation is performed to form the second insulating film, the upper portion of the trench is thermally oxidized to form the third insulating film.
